(19) United States
(12) Patent Application Publication
(10) Pub. No.: US 2024/0206060 A1
(43) Pub. Date: Jun. 20, 2024

(54) RESIN SHEET AND RESIN MULTILAYER SUBSTRATE

(71) Applicant: Murata Manufacturing Co., Ltd., Nagaokakyo-shi (JP)

(72) Inventors: Ryosuke TAKADA, Nagaokakyo-shi (JP); Michiharu NISHIMURA, Nagaokakyo-shi (JP)

(21) Appl. No.: 18/586,832

(22) Filed: Feb. 26, 2024

Related U.S. Application Data
(62) Division of application No. 17/589,087, filed on Jan. 31, 2022.
Application No. 17/589,087 is a continuation of application No. PCT/JP2020/029986, filed on Aug. 5, 2020.

(30) Foreign Application Priority Data
Aug. 6, 2019 (JP) 2019-144542

(51) Int. Cl. H05K 1/03; B32B 3/26; B32B 27/08; C08J 5/04; C08J 5/18; H05K 1/02; H05K 1/11; H05K 3/46

(52) U.S. Cl. CPC H05K 1/0346; B32B 3/263; B32B 27/08; C08J 5/04; C08J 5/18; H05K 1/0271; H05K 1/034; H05K 1/0353; H05K 1/0373; H05K 3/4626; C08J 2325/04; C08J 2327/12; C08J 2365/00; H05K 1/118; H05K 2201/0141; H05K 2201/068; H05K 2203/065

(57) ABSTRACT

A resin sheet that contains one or more kinds of resin materials and a liquid crystal polymer, wherein a weight of the liquid crystal polymer is less than a total weight of the one or more kinds of resin materials. The resin sheet has a thermal expansion coefficient in a plane direction smaller than a thermal expansion coefficient in the plane direction of a comparative resin sheet containing the one or more kinds of resin materials and not containing the liquid crystal polymer.

### CROSS REFERENCE TO RELATED APPLICATIONS

The present application is a divisional of application Ser. No. 17/589,087, filed Jan. 31, 2022, which is a continuation of International application No. PCT/JP2020/029986, filed Aug. 5, 2020, which claims priority to Japanese Patent Application No. 2019-144542, filed Aug. 6, 2019, the entire contents of each of which are incorporated herein by reference.

### FIELD OF THE INVENTION

The present invention relates to a resin sheet and a resin multilayer substrate containing the resin sheet.

### BACKGROUND OF THE INVENTION

In the related art, as a dielectric of a circuit board for high-speed communication, a copper-bonded laminate and a multilayer printed board using a dielectric material having a low dielectric constant and a low dielectric loss tangent have been studied. As dielectric materials having a low dielectric constant and a low dielectric loss tangent, thermoplastic resins such as cyclic olefin polymers and fluororesin materials have been actively developed. On the other hand, a thermoplastic resin having a low dielectric constant and a low dielectric loss tangent has a high thermal expansion coefficient. Therefore, due to the difference between the thermal expansion coefficient of the thermoplastic resin and the thermal expansion coefficient of the copper foil as a conductor, warpage, deterioration in accuracy, and deterioration in handleability occur due to a deformation difference caused by a thermal load.

As an invention related to a resin sheet in the related art, for example, a multilayer printed circuit board disclosed in Patent Document 1 has been known. This multilayer printed circuit board has a structure in which fluorine-based base layers are stacked. The fluorine-based base layer is a prepreg in which glass cloth is impregnated with unsintered PTFE (polytetrafluoroethylene). The thermal expansion coefficient of the glass cloth is lower than the thermal expansion coefficient of PTFE. As a result, the thermal expansion coefficient of the fluorine-based base layer decreases. As a result, in the multilayer printed circuit board disclosed in Patent Document 1, distortion and warpage of the multilayer printed circuit board due to the difference between the thermal expansion coefficient of the conductor layer and the thermal expansion coefficient of the fluorine-based base layer in the multilayer printed circuit board are suppressed.
Patent Document 1: Japanese Patent Application Laid-Open No. 2005-268365

### SUMMARY OF THE INVENTION

When the glass cloth is included in the fluorine-based base layer, the multilayer printed circuit board becomes brittle. Therefore, it is difficult to bend and use such a multilayer printed circuit board.

An object of the present invention is to provide a resin sheet and a resin multilayer substrate capable of suppressing brittleness of the resin sheet while reducing a thermal expansion coefficient of the resin sheet.

Further, an inorganic substance such as glass cloth has a function of reducing the thermal expansion coefficient. However, the inorganic substance such as glass cloth has a high dielectric constant and a high dielectric loss tangent. Therefore, when an inorganic substance such as glass cloth is added to the fluorine-based base layer, the dielectric properties of the fluorine-based base layer are deteriorated. From such a viewpoint, the inventors of the present application have studied a material substituted for an inorganic substance such as glass cloth, and conceived the present application.

A resin multilayer substrate of the present invention contains one or more kinds of resin materials and a liquid crystal polymer, where a weight of the liquid crystal polymer is less than a total weight of the one or more kinds of resin materials, and the resin sheet has a thermal expansion coefficient in a plane direction smaller than a thermal expansion coefficient in the plane direction of a comparative resin sheet containing the one or more kinds of resin materials and not containing the liquid crystal polymer.

According to the present invention, it is possible to suppress a resin sheet from becoming brittle while reducing a thermal expansion coefficient of the resin sheet.

### BRIEF EXPLANATION OF THE DRAWINGS

FIG. 1 is an exploded perspective view of a resin multilayer substrate 10.

FIG. 2 is a cross-sectional view of the resin multilayer substrate 10.

FIG. 3 is a front view of an electronic device 1.

### DETAILED DESCRIPTION OF THE INVENTION

### [Structure of Resin Multilayer Substrate]

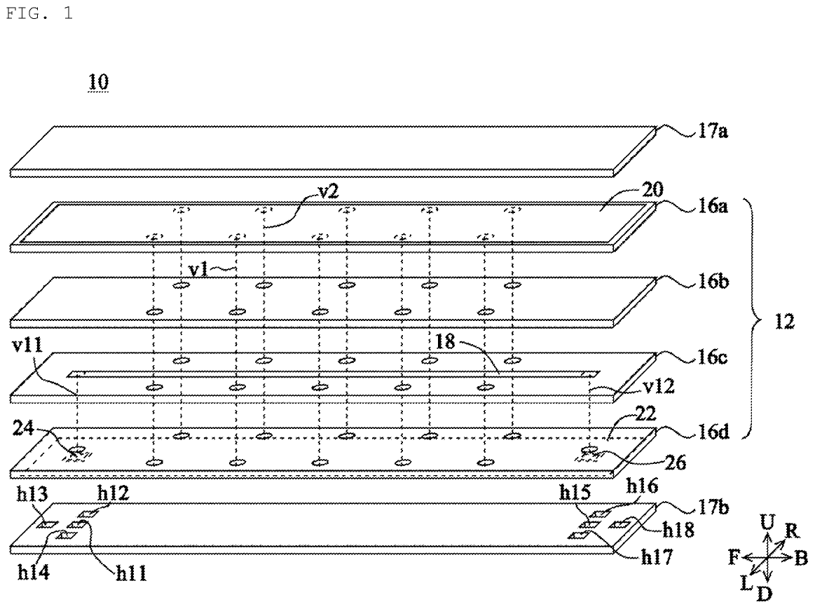

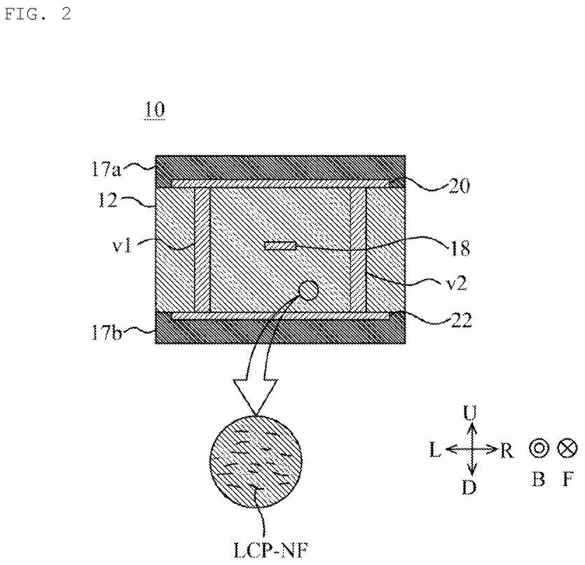

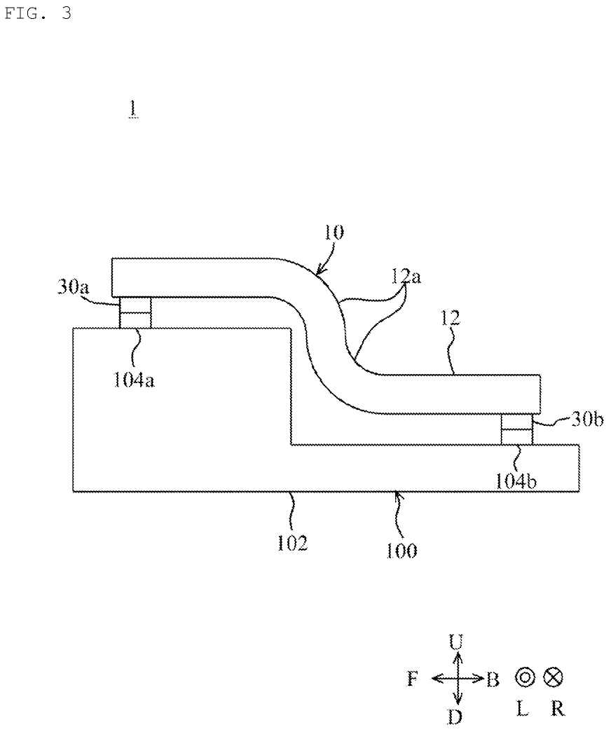

Hereinafter, a structure of a resin multilayer substrate 10 according to an embodiment of the present invention will be described with reference to the drawings. FIG. 1 is an exploded perspective view of the resin multilayer substrate 10. FIG. 2 is a cross-sectional view of the resin multilayer substrate 10. FIG. 3 is a front view of an electronic device 1.

First, in the present specification, directions are defined as follows. A stacking direction of a laminate 12 of the resin multilayer substrate 10 is defined as a vertical direction. A direction in which a signal conductor layer 18 of the resin multilayer substrate 10 extends is defined as a front-rear direction. A line width direction of the signal conductor layer 18 of the resin multilayer substrate 10 is defined as a left-right direction. The vertical direction, the front-rear direction, and the left-right direction are orthogonal to each other. Note that the definition of the directions in the present specification is an example. Therefore, the directions of the resin multilayer substrate 10 at the time of actual use do not need to coincide with the directions in the present specification.

The resin multilayer substrate 10 is used, for example, to connect two circuits in an electronic device such as a mobile phone. As illustrated in FIG. 1, the resin multilayer substrate 10 includes a laminate 12, a signal conductor layer 18, a first ground conductor layer 20, a second ground conductor layer 22, external electrodes 24 and 26, a plurality of first interlayer connecting conductors v1, a plurality of second interlayer connecting conductors v2, and interlayer connecting conductors v11 and v12.

In FIG. 1, representative interlayer connecting conductors, conductor non-forming portions, and voids among the plurality of first interlayer connecting conductors v1 and the plurality of second interlayer connecting conductors v2 are denoted by reference numerals.

The laminate 12 has a plate shape. As illustrated in FIG. 1, the laminate 12 has a rectangular shape having long sides extending in the front-rear direction when viewed in the vertical direction. Therefore, the length of the laminate 12 in the front-rear direction is longer than the length of the laminate 12 in the left-right direction. The length of the laminate 12 in the front-rear direction is longer than the length of the laminate 12 in the vertical direction. The laminate 12 has flexibility.

As illustrated in FIG. 1, the laminate 12 has a structure in which resin sheets 16a to 16d and resist layers 17a and 17b are stacked in the vertical direction (stacking direction). The resist layer 17a, the resin sheets 16a to 16d, and the resist layer 17b are stacked in this order from the top to the bottom. The resin sheets 16a to 16d are dielectric sheets having flexibility. Materials of the resin sheets 16a to 16d will be described later. The resin sheets 16a to 16d have the same rectangular shape as the laminate 12 when viewed in the vertical direction. Further, details of the resist layers 17a and 17b will be described later.

The signal conductor layer 18 is provided in the laminate 12 as illustrated in FIG. 1. More specifically, the signal conductor layer 18 is provided on an upper surface of the resin sheet 16c. As a result, the signal conductor layer 18 is provided in the laminate 12. The signal conductor layer 18 has a linear shape extending in the front-rear direction. The signal conductor layer 18 is disposed at the center of the upper surface of the resin sheet 16c in the left-right direction. A front end of the signal conductor layer 18 is located at a front end portion of the resin sheet 16c. A rear end of the signal conductor layer 18 is located at a rear end portion of the resin sheet 16c. A high-frequency signal is transmitted to the signal conductor layer 18.

The first ground conductor layer 20 is provided in the laminate 12. The first ground conductor layer 20 is disposed on the signal conductor layer 18 so as to overlap the signal conductor layer 18 when viewed in the vertical direction. The first ground conductor layer 20 is provided on the upper surface of the resin sheet 16a. As illustrated in FIG. 1, the first ground conductor layer 20 has a rectangular shape having long sides extending in the front-rear direction when viewed in the vertical direction. The first ground conductor layer 20 has a shape substantially coinciding with the laminate 12 when viewed in the vertical direction. However, the first ground conductor layer 20 is slightly smaller than the laminate 12 when viewed in the vertical direction. A ground potential is connected to the first ground conductor layer 20.

The second ground conductor layer 22 is provided in the laminate 12. The second ground conductor layer 22 is disposed under the signal conductor layer 18 so as to overlap the signal conductor layer 18 when viewed in the vertical direction. More specifically, the second ground conductor layer 22 is provided on the lower surface of a resin sheet 16d. As illustrated in FIG. 1, the second ground conductor layer 22 has a rectangular shape having long sides extending in the front-rear direction when viewed in the vertical direction. The second ground conductor layer 22 has a shape substantially coinciding with the laminate 12 when viewed in the vertical direction. However, the second ground conductor layer 22 is slightly smaller than the laminate 12 when viewed in the vertical direction. A ground potential is connected to the second ground conductor layer 22. The signal conductor layer 18, the first ground conductor layer 20, and the second ground conductor layer 22 as described above have a stripline structure as illustrated in FIG. 2.

The external electrode 24 is provided at the left end portion of the lower surface of the resin sheet 16d. The external electrode 24 has a rectangular shape when viewed in the vertical direction. The second ground conductor layer 22 is not provided around the external electrode 24 so that the external electrode 24 is insulated from the second ground conductor layer 22. The external electrode 24 overlaps the front end portion of the signal conductor layer 18 when viewed in the vertical direction. The high-frequency signal is input to and output from the signal conductor layer 18 via the external electrode 24. The external electrode 26 has a front-back symmetrical structure with the external electrode 24. Therefore, the description of the external electrode 26 is omitted.

The resist layers 17a and 17b are flexible protective layers. The resist layers 17a and 17b have the same rectangular shape as the laminate 12 when viewed in the vertical direction. The resist layer 17a covers the entire upper surface of the resin sheet 16a. Thus, the resist layer 17a protects the first ground conductor layer 20.

The resist layer 17b covers substantially the entire lower surface of the resin sheet 16d. Thus, the resist layer 17b protects the second ground conductor layer 22. However, openings h11 to h18 are provided in the resist layer 17b. The opening h11 overlaps the external electrode 24 when viewed in the vertical direction. As a result, the external electrode 24 is exposed to the outside from the resin multilayer substrate 10 through the opening h11. The opening h12 is provided on the right of the opening h11. The opening h13 is provided in front of the opening h11. The opening h14 is provided on the left of the opening h11. As a result, the second ground conductor layer 22 is exposed to the outside from the resin multilayer substrate 10 through the openings h12 to h14. Each of the openings h15 to h18 has a front-back symmetrical structure with the openings h11 to h14. Therefore, the description of the openings h15 to h18 is omitted.

The signal conductor layer 18, the first ground conductor layer 20, the second ground conductor layer 22, and the external electrodes 24 and 26 as described above are formed by, for example, etching a copper foil provided on the upper surface or the lower surface of the resin sheets 16a to 16d.

The plurality of first interlayer connecting conductors v1 are provided on the laminate 12 so as to be located on the left of the signal conductor layer 18. The plurality of first interlayer connecting conductors v1 are arranged in a line at equal intervals in the front-rear direction. The plurality of first interlayer connecting conductors v1 penetrate the resin sheets 16a to 16d in the vertical direction. As illustrated in FIG. 2, upper ends of the plurality of first interlayer connecting conductors v1 are connected to the first ground conductor layer 20. As illustrated in FIG. 2, lower ends of the plurality of first interlayer connecting conductors v1 are connected to the second ground conductor layer 22. Thus, the plurality of first interlayer connecting conductors v1 electrically connect the first ground conductor layer 20 and the second ground conductor layer 22.

The plurality of second interlayer connecting conductors v2 are provided on the laminate 12 so as to be located on the right of the signal conductor layer 18. The plurality of second interlayer connecting conductors v2 are arranged in a line at equal intervals in the front-rear direction. The plurality of second interlayer connecting conductors v2 penetrate the resin sheets 16a to 16d in the vertical direction. As illustrated in FIG. 2, upper ends of the plurality of second interlayer connecting conductors v2 are connected to the first ground conductor layer 20. As illustrated in FIG. 2, lower ends of the plurality of second interlayer connecting conductors v2 are connected to the second ground conductor layer 22. Thus, the plurality of second interlayer connecting conductors v2 electrically connect the first ground conductor layer 20 and the second ground conductor layer 22.

The interlayer connecting conductor v11 is provided at the front end portions of the resin sheets 16c and 16d. The interlayer connecting conductor v11 penetrates the resin sheets 16c and 16d in the vertical direction. The upper end of the interlayer connecting conductor v11 is connected to the front end portion of the signal conductor layer 18. The lower end of the interlayer connecting conductor v11 is connected to the external electrode 24. As a result, the interlayer connecting conductor v11 electrically connects the signal conductor layer 18 and the external electrode 24. The interlayer connecting conductor v12 has a front-rear symmetric structure with the interlayer connecting conductor v11. Therefore, the description of the interlayer connecting conductor v12 is omitted.

The plurality of first interlayer connecting conductors v1, the plurality of second interlayer connecting conductors v2, and the interlayer connecting conductors v11 and v12 as described above are via hole conductors. The formation of the via hole conductor is as follows. Through-holes are formed in the resin sheets 16a to 16d by a laser beam. A conductive paste which is a mixture of metal and a resin is filled in the through-hole. When the resin sheets 16a to 16d are thermocompression-bonded, the conductive paste is fired to form a via hole conductor. By using the conductive paste, the plurality of first interlayer connecting conductors v1, the plurality of second interlayer connecting conductors v2, and the interlayer connecting conductors v11 and v12 can be connected at the time of collectively heating and pressing the resin sheets 16a to 16d. Therefore, the plurality of first interlayer connecting conductors v1, the plurality of second interlayer connecting conductors v2, and the interlayer connecting conductors v11 and v12 can be easily formed, and the degree of freedom of arrangement of the plurality of first interlayer connecting conductors v1, the plurality of second interlayer connecting conductors v2, and the interlayer connecting conductors v11 and v12 is increased.

Next, the electronic device 1 including a resin multilayer substrate 10 will be described with reference to FIG. 3. The electronic device 1 includes the resin multilayer substrate 10 and a circuit board 100. The resin multilayer substrate 10 further includes connectors 30a and 30b. The connector 30a is mounted on the front end portion of the lower surface of the resist layer 17b. The connector 30a includes a central conductor and an outer conductor. The central conductor is electrically connected to the external electrode 24 by soldering. The outer conductor is electrically connected to the second ground conductor layer 22 by soldering.

The connector 30b is mounted on the rear end portion of the lower surface of the resist layer 17b. The connector 30b includes a central conductor and an outer conductor. The central conductor is electrically connected to the external electrode 26 by soldering. The outer conductor is electrically connected to the second ground conductor layer 22 by soldering.

The circuit board 100 includes a substrate body 102 and connectors 104a and 104b. The substrate body 102 has a plate shape. The connector 104a is mounted on the upper surface of the front portion of the substrate body 102. The connector 104a includes a central conductor and an outer conductor. The central conductor of the connector 104a is connected to the central conductor of the connector 30a. The outer conductor of the connector 104a is connected to the outer conductor of the connector 30a.

The connector 104b is mounted on the upper surface of the rear portion of the substrate body 102. The connector 104b includes a central conductor and an outer conductor. The central conductor of the connector 104b is connected to the central conductor of the connector 30b. The outer conductor of the connector 104b is connected to the outer conductor of the connector 30b.

Meanwhile, as illustrated in FIG. 3, the position of the connector 104a in the vertical direction is different from the position of the connector 104b in the vertical direction. Therefore, the resin multilayer substrate 10 is bent to be used. Specifically, the upper surface of the laminate 12 is mountain folded, and the upper surface of the laminate 12 is valley folded. As described above, the resin multilayer substrate 10 has the bent portion 12a in which the stacking direction of the resin sheets 16a to 16d changes.

### [Resin Material of Resin Sheet]

Next, a resin material of the resin sheet according to the present embodiment will be described. A resin sheet before stacking is distinguished from the resin sheets 16a to 16d after stacking, and is referred to herein as a resin sheet 16.

The material of the resin sheet 16 preferably has a low relative permittivity and a low dielectric loss tangent from the viewpoint of high-frequency characteristics. Examples of such a material having a low relative permittivity and a low dielectric loss tangent include perfluoroalkoxy alkane (PFA), cyclic olefin polymer (COP), and syndiotactic polystyrene (SPS). As the PFA, for example, Fluon+EA 2000 manufactured by AGC Inc. can be used. For the COP, for example, ZEONOR manufactured by Zeon Corporation can be used. For SPS, Oidys manufactured by KURABO INDUSTRIES LTD. can be used, for example. When the resin sheet 16 contains a resin material having a small relative permittivity and a small dielectric loss tangent such as PFA, COP, or SPS, the resin multilayer substrate 10 having the excellent high-frequency characteristics is obtained.

However, the resin materials having a small relative permittivity and a small dielectric loss tangent such as PFA, COP, and SPS have a large thermal expansion coefficient as shown in Table 1. Tables showing physical property values of PFA, COP, SPS, and LCP (liquid crystal polymer).

TABLE 1

| | | | Thermal | Water |
|---|---|---|---|---|
| | | | expansion | absorption |
| | Relative | dielectric | coefficient | rate |
| | permittivity | loss tangent | ppm/° C. | % |
| LCP | 3 | 0.002 | <20 | 0.04 |
| PFA | 2.1 | <0.001 | 200< | <0.01 |
| COP | 2.3 | <0.001 | 60< | <0.01 |
| SPS | 2.3 | 0.001-0.002 | 60< | 0.12 |

When the thermal expansion coefficient of the resin material of the resin sheet 16 increases, as described below, distortion or warpage may occur in the resin multilayer substrate 10 at the time of manufacturing the resin multilayer substrate 10. The resin multilayer substrate 10 includes conductor layers like the signal conductor layer 18, the first ground conductor layer 20, and the second ground conductor layer 22. The material of the conductor layer is, for example, copper. The thermal expansion coefficient of copper is about 16. On the other hand, as shown in Table 1, the thermal expansion coefficient of PFA is larger than 200. The thermal expansion coefficient of the COP is 60 or more. The thermal expansion coefficient of the SPS is greater than 60. As described above, the thermal expansion coefficient of a resin material having a small relative permittivity and a small dielectric loss tangent such as PFA, COP, or SPS may be larger than the thermal expansion coefficient of copper. Therefore, in the thermocompression bonding step, there is a difference between the elongation amount per unit length of the resin sheet 16 and the elongation amount per unit length of the signal conductor layer 18, the first ground conductor layer 20, and the second ground conductor layer 22. As a result, the resin multilayer substrate 10 may be distorted or warped.

Therefore, the inventors of the present application designed the resin material of the resin sheet 16 as follows. The resin sheet 16 contains one or more kinds of resin materials, and the liquid crystal polymer having a weight less than a total weight of the one or more kinds of resin materials. The one or more kinds of resin materials are portions of the resin material contained in the resin sheet 16 excluding the liquid crystal polymer. The one or more kinds of resin materials have a thermal expansion coefficient larger than the thermal expansion coefficient of the LCP. As a result, the resin sheet 16 has a thermal expansion coefficient in the plane direction smaller than the thermal expansion coefficient of a first comparative resin sheet in the plane direction. The first comparative resin sheet is a resin sheet that contains one or more kinds of resin materials and does not contain the LCP. The first comparative resin sheet has the same structure as that of the resin sheet 16. The thermal expansion coefficient of the resin sheet 16 in the plane direction is preferably, for example, 5 ppm/° C. to 20 ppm/° C. The thermal expansion coefficient of the resin sheet 16 in the plane direction is more preferably 10 ppm/° C. to 20 ppm/° C.

The thermal expansion coefficient in the plane direction is expressed by the following formula (A):

$$Δ L = α L Δ T \qquad ( A )$$

α: thermal expansion coefficient in direction (plane direction) in which main surface of resin sheet 16 spreads;
L: length of resin sheet 16 in direction (plane direction) in which main surface of resin sheet 16 spreads;
ΔL: elongation amount of resin sheet 16 in direction (plane direction) in which main surface of resin sheet 16 spreads; and
ΔT: temperature rise.

The inventors of the present application measured the thermal expansion coefficient by the following method. The inventors of the present application prepared a sample cut into a width of 5 mm and a length of 16 mm. Then, the inventors of the present application heated the sample from room temperature to 170° C. in a tensile mode with a load of 0.1 N using a thermomechanical analyzer (trade name: TMA Q 400) manufactured by TA instruments. Then, the inventors of the present application measured the thermal expansion coefficient by determining the average value of the thermal expansion coefficients within the range of 50° C. to 80° C. in the process of cooling the sample to room temperature.

Furthermore, the relative permittivity of the one or more kinds of resin materials is smaller than the relative permittivity of the LCP. The dielectric loss tangents of the one or more kinds of resin materials is smaller than the relative permittivity of the LCP.

The one or more kinds of resin materials are, for example, fluororesins. The fluororesin is, for example, PFA. The thermal expansion coefficient of PFA is larger than the thermal expansion coefficient of the LCP as shown in Table 1. Further, the relative permittivity of the PFA is smaller than the relative permittivity of the LCP. The dielectric loss tangent of the PFA is smaller than the dielectric loss tangent of the LCP.

The one or more kinds of resin materials may be, for example, COP. The thermal expansion coefficient of the COP is larger than the thermal expansion coefficient of the LCP as shown in Table 1. Further, the relative permittivity of the COP is smaller than the relative permittivity of the LCP. In addition, the dielectric loss tangent of the COP is smaller than the dielectric loss tangent of the LCP.

The one or more kinds of resin materials may be, for example, SPS. The thermal expansion coefficient of SPS is larger than the thermal expansion coefficient of the LCP as shown in Table 1. Further, the relative permittivity of the SPS is smaller than the relative permittivity of the LCP. The dielectric loss tangent of the SPS is smaller than the dielectric loss tangent of the LCP.

As described above, the resin sheet 16 contains one or more kinds of resin materials having a thermal expansion coefficient larger than a thermal expansion coefficient of the LCP, and the LCP having a weight less than a total weight of the one or more kinds of resin materials. Therefore, the thermal expansion coefficient of the resin sheet 16 in the plane direction is smaller than the thermal expansion coefficient of the first comparative resin sheet that contains one or more kinds of resin materials and does not contain the LCP in the plane direction. Therefore, the thermal expansion coefficient of the resin sheet 16 in the plane direction approaches the thermal expansion coefficient of the conductor layer. As a result, the occurrence of distortion and warpage in the resin multilayer substrate 10 at the time of manufacturing the resin multilayer substrate 10 is suppressed. In particular, when the thermal expansion coefficient of the resin sheet 16 in the plane direction is 20 ppm/° C. or less, the occurrence of distortion and warpage in the resin multilayer substrate 10 at the time of manufacturing the resin multilayer substrate 10 is effectively suppressed.

Further, the LCP has flexibility unlike glass cloth. Therefore, although the resin sheet 16 contains the LCP, the resin sheet 16 is suppressed from becoming brittle. As a result, the resin multilayer substrate 10 having excellent flexibility can be obtained.

In addition, the relative permittivity of the one or more kinds of resin materials is smaller than the relative permittivity of the LCP. As a result, the relative permittivity of the resin sheet 16 is lower than the relative permittivity of the second comparative resin sheet containing only the LCP as the resin material. As a result, the high-frequency characteristics of the resin multilayer substrate 10 are improved.

When the dielectric loss tangent of the one or more kinds of resin materials is smaller than the dielectric loss tangent of the LCP, the dielectric loss tangent of the resin sheet 16 is lower than the dielectric loss tangent of the second comparative resin sheet containing only the LCP as the resin material. As a result, the high-frequency characteristics of the resin multilayer substrate 10 are improved.

When the amount of LCP contained in the resin sheet 16 increases, the thermal expansion coefficient of the resin sheet 16 in the plane direction decreases. However, if the amount of LCP contained in the resin sheet 16 becomes excessively large, the relative permittivity and the dielectric loss tangent of the resin sheet 16 become large. In this case, it is difficult to obtain the excellent high-frequency characteristics in the resin multilayer substrate 10. Therefore, the resin sheet 16 only needs to contain the LCP of a weight less than the total weight of one or more kinds of resin materials. The resin sheet 16 preferably contains 100 parts by weight of one or more kinds of resin materials and 10 parts by weight to 70 parts by weight of the LCP. The resin sheet 16 more preferably contains 100 parts by weight of one or more kinds of resin materials and 15 parts by weight to 50 parts by weight of the LCP. The resin sheet 16 particularly preferably contains 100 parts by weight of one or more kinds of resin materials and 20 parts by weight to 40 parts by weight of the LCP.

### [LCP-NF]

As illustrated in FIG. 2, the LCP preferably contains fibrous particles. Specifically, the LCP is preferably LCP-NF (nanofiber liquid crystal polymer). The LCP-NF will be described below.

The LCP-NF includes a fiber portion and a lump-shaped portion. The fiber portion may be contained in the LCP-NF as an aggregation portion in which fibrous particles are aggregated, or the lump-shaped portion may be contained in the LCP as an aggregation portion in which lump-shaped particles are contained and aggregated. The LCP-NF may not include the lump-shaped portion.

The fiber portion is a fibrous particle. In the present embodiment, the fibrous particles are LCP particles having an aspect ratio of 10 times or more, the aspect ratio being a ratio of a length in a longitudinal direction to a fiber diameter. The length in the longitudinal direction and the fiber diameter of the fibrous particles can be measured from image data of the fibrous particles obtained when the fibrous particles are observed with a scanning electron microscope.

In the LCP-NF, the fibrous particles have an average diameter of 1 μm or less. The value of the average diameter of the fiber portions is an average value of fiber diameters of a plurality of fibrous particles constituting the fiber portion. As described above, the LCP-NF according to the present embodiment contains fine fibrous particles.

The lump-shaped portion is LCP-NF that is not substantially fibrous. The lump-shaped portion may have a flat outer shape. In the LCP-NF, the content of the lump-shaped portion is 20% or less. That is, in the LCP-NF, the content of the lump-shaped portion is relatively low, or the LCP-NF does not contain the lump-shaped portion. The content rate of the lump-shaped portion is evaluated by the number of lump-shaped portions with respect to the number of aggregation portions contained in the LCP-NF. An aggregation portion having a maximum height of more than 10 μm when the LCP-NF is placed on a plane is a lump-shaped portion, and an aggregation portion having a maximum height of 10 μm or less is a fiber portion.

As described above, when the LCP is the LCP-NF, the thermal expansion coefficient of the resin sheet 16 in the plane direction becomes smaller. Specifically, the fibrous particles have an aspect ratio of 10 times or more, the aspect ratio being a ratio of a length in a longitudinal direction to a fiber diameter. Furthermore, the fibrous particles have an average diameter of 1 μm or less. Such an LCP-NF has a property of having a large surface area. Therefore, the LCP-NF easily close contacts to other members (that is, one or more kinds of resin materials). Further, the thermal expansion coefficient in the longitudinal direction of the main chain structure of the LCP-NF is negative. As a result, when the temperature of the resin sheet 16 rises, the LCP-NF effectively prevents one or more kinds of resin materials from extending. Therefore, when the LCP is the LCP-NF, the thermal expansion coefficient of the resin sheet 16 in the plane direction becomes smaller. In addition, since the resin sheet 16 contains a small amount of LCP-NP, the thermal expansion coefficient of the resin sheet 16 in the plane direction becomes sufficiently small.

Also for the following reasons, since the LCP is the LCP-NF, the thermal expansion coefficient of the resin sheet 16 in the plane direction becomes smaller. More specifically, at the time of forming the resin sheet 16, a solution in which one or more kinds of resin materials are melted in a solvent is produced. Further, the LCP-NF is mixed with the solution. This solution is spread on a metal plate by spin coating or the like. Then, the solvent is volatilized in a drying step. As the solvent volatilizes, the thickness of the solution decreases. The LCP-NF is a fibrous particle. Therefore, the fibrous particle falls down in the solution. As a result, the longitudinal direction of the main chain structure of the LCP-NF is a direction along the plane direction of the resin sheet 16 as illustrated in FIG. 2. As described above, the thermal expansion coefficient in the longitudinal direction of the main chain structure of the LCP-NF is negative. As a result, when the temperature of the resin sheet 16 rises, the LCP-NF effectively prevents one or more kinds of resin materials from extending in the plane direction. As described above, when the LCP is the LCP-NF, the thermal expansion coefficient of the resin sheet 16 in the plane direction becomes smaller. In addition, since the resin sheet 16 contains a small amount of LCP-NP, the thermal expansion coefficient of the resin sheet 16 in the plane direction becomes sufficiently small.

The LCP-NF is made of a thermotropic liquid crystal polymer. The LCP-NF is heated to 400° C. under an inert atmosphere, then cooled to normal temperature at a temperature decreasing rate of 40° C./min or more, and heated again at a temperature increasing rate of 40° C./min while an endothermic peak temperature measured using a differential scanning calorimeter exceeds 330° C. As a result, the LCP-NF has high heat resistance and can be used as an electronic material. In the present specification, the endothermic peak temperature measured as described above may be simply referred to as a “melting point”.

The LCP-NF preferably has a D50 value of 13 μm or less as measured by particle size measurement using a particle size distribution measuring apparatus by a laser diffraction scattering method.

### [Method for Manufacturing Resin Sheet 16]

Next, a method for manufacturing the resin sheet 16 will be described. In the method for manufacturing the resin sheet 16, first, LCP-NF is produced. The method for manufacturing LCP-NF includes a coarse pulverization step, a fine pulverization step, a coarse particle removing step, and a fiberization step in this order.

In the coarse pulverization step, first, a molded product of LCP is prepared as a raw material. Examples of the molded product of LCP include uniaxially oriented pellet-like, biaxially oriented film-like, or powdery LCP. As the molded product of the LCP, the pellet-like or powdery LCP is preferable, and the pellet-like LCP is more preferable from the viewpoint of manufacturing cost and the like. The molded product of LCP does not include fibrous LCP directly molded by an electrolytic spinning method, a melt blowing method, or the like. However, the molded product of the LCP may contain LCP processed into a fibrous shape by crushing the pellet-like LCP or the powdery LCP.

The melting point of the molded product of LCP is preferably higher than 330° C., and more preferably 350° C. or higher. As a result, a highly heat resistant LCP-NF suitable as a material for an electronic component is obtained.

Next, the molded product of LCP is coarsely pulverized to obtain coarsely pulverized LCP. For example, the LCP molded product is coarsely pulverized by a cutter mill device to obtain coarsely pulverized LCP. The size of the particles of the coarsely pulverized LCP is not particularly limited as long as the particles can be used as a raw material in the fine pulverization step described later. The maximum particle size of the coarse pulverized LCP is, for example, 3 mm or less.

The method for manufacturing LCP-NF may not necessarily include the coarse pulverization step. For example, if the molded product of LCP can be used as a raw material in the fine pulverization step, the molded product of LCP may be directly used as a raw material in the fine pulverization step.

In the fine pulverization step, coarse powder LCP as LCP is pulverized in a state of being dispersed in liquid nitrogen to obtain granular finely pulverized LCP. In the fine pulverization step, the coarse pulverized LCP dispersed in the liquid nitrogen is pulverized using a medium. The medium is, for example, a bead. In the fine pulverization step, it is preferable to use a bead mill having relatively few technical problems from the viewpoint of handling liquid nitrogen. Examples of the apparatus that can be used in the fine pulverization step include “LNM-08” which is a liquid nitrogen bead mill manufactured by AIMEX CO., LTD.

In the fine pulverization step, a pulverization method in which the LCP is pulverized in a state of being dispersed in liquid nitrogen is different from a freeze pulverization method in the related art. The freeze pulverization method in the related art is a method of pulverizing a raw material to be pulverized while pouring liquid nitrogen onto the raw material to be pulverized and a pulverizer main body, but the liquid nitrogen is vaporized at the time when the raw material to be pulverized is pulverized. That is, in the freeze pulverization method in the related art, the raw material to be pulverized is not dispersed in liquid nitrogen at the time when the raw material to be pulverized is pulverized.

In the freeze pulverization method in the related art, the heat of the raw material to be pulverized itself, the heat generated from the pulverizer, and the heat generated by pulverizing the raw material to be pulverized vaporize liquid nitrogen in an extremely short time. Therefore, in the freeze pulverization method in the related art, the raw material during pulverization located inside the pulverizer has a temperature much higher than −196° C., which is the boiling point of liquid nitrogen. That is, in the freeze pulverization method in the related art, pulverization is performed under the condition that the internal temperature of the pulverizer is usually about 0° C. to 100° C. In the freeze pulverization method in the related art, although when the liquid nitrogen is supplied as much as possible, the temperature inside the pulverizer is approximately −150° C. at the lowest temperature.

For this reason, in the freeze pulverization method in the related art, for example, in the case of pulverizing the uniaxially oriented pellet-like LCP or the coarsely pulverized product of the pellet-like LCP, pulverization proceeds along a plane substantially parallel to the axial direction of the molecular axis of the LCP, and thus, fibrous LCP having a large aspect ratio and a fiber diameter much larger than 1 μm is obtained. That is, although the uniaxially oriented pellet-like LCP or the coarsely pulverized product of the pellet-like LCP is pulverized in the freeze pulverization direction in the related art, the granular finely pulverized LCP cannot be obtained.

Since the raw material to be pulverized is pulverized in a state of being dispersed in liquid nitrogen, the raw material in a further cooled state can be pulverized as compared with the freeze pulverization method in the related art. Specifically, the raw material to be pulverized can be pulverized at a temperature lower than −196° C., which is the boiling point of the liquid nitrogen. When the raw material to be pulverized having a temperature lower than −196° C. is pulverized, the brittle fracture of the raw material to be pulverized is repeated, so that the pulverization of the raw material proceeds. As a result, for example, although when the uniaxially oriented LCP is pulverized, not only the fracture progresses in the plane substantially parallel to the axial direction of the molecular axis of the LCP, but also the brittle fracture progresses along the plane intersecting the axial direction, so that the granular finely pulverized LCP can be obtained.

In the fine pulverization step, the impact is continuously applied to the granular LCP formed by the brittle fracture in the liquid nitrogen with a medium or the like in a brittle state. As a result, in the LCP obtained in the fine pulverization step, a plurality of fine cracks are formed from the outer surface to the inside.

The granular finely pulverized LCP obtained by the fine pulverization step preferably has a D50 of 50 μm or less as measured by a particle size distribution measuring apparatus by a laser diffraction scattering method. This makes it possible to suppress clogging of the granular finely pulverized LCP with the nozzle in the following fiberization step.

In the coarse particle removing step, coarse particles are removed from the granular finely pulverized LCP obtained in the fine pulverization step. For example, the granular finely pulverized LCP is sieved with a mesh to obtain the granular finely pulverized LCP under the sieve, and the coarse particles contained in the granular finely pulverized LCP can be removed by removing the granular LCP on the sieve. The type of mesh may be appropriately selected, and examples of the mesh include a mesh having an opening of 53 μm. The method for manufacturing LCP-NF may not necessarily include the coarse particle removing step.

In the fiberization step, the granular LCP is crushed by a wet high-pressure crushing device to obtain LCP-NF. In the fiberization step, first, the finely pulverized LCP is dispersed in a dispersion medium. In the finely pulverized LCP to be dispersed, coarse particles may not be removed, but it is preferable that the coarse particles are removed. Examples of the dispersion medium include water, ethanol, methanol, isopropyl alcohol, toluene, benzene, xylene, phenol, acetone, methyl ethyl ketone, diethyl ether, dimethyl ether, hexane, and mixtures thereof.

Next, the finely pulverized LCP in a state of being dispersed in the dispersion medium, that is, slurry-like finely pulverized LCP is passed through a nozzle in a state of being pressurized at high pressure. By passing through the nozzle at a high pressure, shearing force or collision energy due to high-speed flow in the nozzle acts on the LCP, and the granular finely pulverized LCP is crushed, so that the fiberization of the LCP proceeds and LCP-NF can be obtained. The nozzle diameter of the nozzle is preferably as small as possible within a range in which clogging of the finely pulverized LCP does not occur in the nozzle from the viewpoint of applying high shear force or high collision energy. Since the granular finely pulverized LCP has a relatively small particle size, the nozzle diameter in the wet high-pressure crushing device used in the fiberization step can be reduced. The nozzle diameter is, for example, 0.2 mm or less.

As described above, a plurality of fine cracks are formed in the granular finely pulverized LCP-NF. Therefore, the dispersion medium enters into the finely pulverized LCP through fine cracks by pressurization in a wet high-pressure disperser. Then, when the slurry-like finely pulverized LCP passes through the nozzle and is positioned under normal pressure, the dispersion medium that has entered the finely pulverized LCP expands in a short time. When the dispersion medium that has entered the finely pulverized LCP expands, destruction progresses from the inside of the finely pulverized LCP. Therefore, the fiberization proceeds to the inside of the finely pulverized LCP, and the molecules of the LCP are separated into domain units arranged in one direction. As described above, in the fiberization step, by defibrating the granular finely pulverized LCP obtained in the fine pulverization step, it is possible to obtain LCP-NF having a lower content rate of the lump-shaped portion and a fine fibrous shape than LCP-NF obtained by crushing the granular LCP obtained by the freeze pulverization method in the related art.

As for the method for producing the resin sheet 16 containing LCP-NF, the resin sheet 16 can be manufactured by any of solution film formation in which a resin is dissolved in a solvent, dispersion coating in which a resin is dispersed in a solvent, and a melt film formation in which a resin is melted at a melting temperature or higher and molded. First, a method for forming a resin sheet by a solution film forming method will be described. A solution in which one or more kinds of resin materials are dissolved in a solvent is produced. The one or more kinds of resin materials are, for example, PFA, COP, SPS, and the like. The solvent is a liquid capable of dissolving one or more kinds of resin materials such as PFA, COP, and SPS. Examples of such a solvent include toluene, xylene, N-methylpyrrolidone, dimethylformamide, dimethylacetamide, methyl ethyl ketone, aliphatic alcohol, and water.

Furthermore, the LCP-NF is mixed with the solution. However, the solvent cannot dissolve the LCPNF. Furthermore, the solvent does not break a structure of the LCP-NF. Therefore, the LCP-NF is dispersed in a solution in which one or more kinds of resin materials are dissolved in a solvent while maintaining the state of fibrous particles.

Next, the solution is thinly applied onto the metal plate by spin coating. Then, the applied solution is dried to volatilize the solvent in the solution. Thus, the resin sheet 16 is completed.

The resin sheet 16 may be formed by a melt film-forming method. First, a mixed material obtained by mixing one or more kinds of resin materials and the LCP-NF is prepared. The one or more kinds of resin materials are, for example, PFA, COP, SPS, and the like.

Further, one or more kinds of resin materials of the mixed material are melted by heating the mixed material. However, in the melted mixed material, one or more kinds of resin materials are melted, and the LCP-NF is not melted. Furthermore, the structure of the LCP-NF does not collapse due to heating of the mixed material. Therefore, the highest melting point among the melting points of the one or more kinds of resin materials is preferably 30° C. or more lower than the melting point of the LCP-NF (liquid crystal polymer). The one or more kinds of resin materials are heat-resistant thermoplastic resins whose composition does not collapse by heating. Thereafter, the melted mixed material is processed into a sheet shape by extrusion molding. Thus, the resin sheet 16 is completed.

### Other Embodiments

The resin sheet according to the present invention is not limited to the resin sheets 16, 16a to 16d according to the above embodiment, and can be modified within the scope of the gist thereof.

The resin sheets 16, 16a to 16d may contain one or more kinds of resin materials having a thermal expansion coefficient larger than the thermal expansion coefficient of the LCP. Therefore, the resin sheets 16, 16a to 16d may contain one kind of resin material having a thermal expansion coefficient larger than the thermal expansion coefficient of the LCP, or may contain two or more kinds of resin materials having a thermal expansion coefficient larger than the thermal expansion coefficient of the LCP.

In the resin sheets 16, 16a to 16d, the content of one or more kinds of resin materials is preferably larger than 50% of the entire resin sheets 16, 16a to 16d.

From the viewpoint of high-frequency characteristics of the resin multilayer substrate 10, the relative permittivity of one or more kinds of resin materials is preferably smaller than the relative permittivity of the LCP. This does not prevent the relative permittivity of the one or more kinds of resin materials from being equal to or higher than the relative permittivity of the LCP.

From the viewpoint of high-frequency characteristics of the resin multilayer substrate 10, the dielectric loss tangent of one or more kinds of resin materials is preferably smaller than the dielectric loss tangent of the LCP. This does not prevent the dielectric loss tangent of the one or more kinds of resin materials from being equal to or higher than the dielectric loss tangent of the LCP.

In the resin sheets 16, 16a to 16d, the LCP may not be the LCP-NF. Even when the LCP is not the LCP-NF, the thermal expansion coefficient of the resin sheets 16, 16a to 16d in the plane direction can be reduced. When the LCP is not the LCP-NF, it is preferable that the solvent can melt one or more kinds of resin materials and the LCP at the time of manufacturing the resin sheet 16. Therefore, one or more kinds of resin materials and the LCP are uniformly mixed in the resin sheets 16, 16a to 16d. As a result, various characteristics of the resin sheets 16, 16a to 16d become uniform. When the LCP is not the LCP-NF, at the time of manufacturing the resin sheet 16, the one or more kinds of resin materials of the mixed material and the LCP are melted by heating the mixed material. Therefore, one or more kinds of resin materials and the LCP are uniformly mixed in the resin sheets 16, 16a to 16d. As a result, various characteristics of the resin sheets 16, 16a to 16d become uniform.

The one or more kinds of resin materials may be, for example, a norbornene-based polymer containing at least one of repeating units represented by the following General Formula (1).

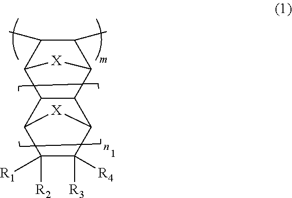

In the General Formula (1), X represents O, —CH₂— or —CH₂—CH₂—; and each of substituents R₁, R₂, R₃, and R₄ represents a group containing a group selected from hydrogen, a linear or branched organic group, or a derivative in which a part of these linear or branched organic groups is substituted with halogen, a nitrile group, or the like. Examples of the linear or branched organic group include an alkyl group, an alkenyl group, an alkynyl group, an aryl group, an aralkyl group, an alkoxysilyl group, an organic group containing an epoxy group, an organic group containing an ether group, an organic group containing a (meth)acrylic group, an organic group containing an ester group, and an organic group containing a ketone group. These groups may be bonded via an alkyl group, an ether group, or an ester group, and may be the same as or different from each other. m is an integer of 10 to 10000; and n₁ is an integer of 0 to 5.

The substituents R₁, R₂, R₃, and R₄ of the addition-type polynorbornene having a structure represented by General Formula (1) can have predetermined characteristics by adjusting the type and the ratio of repeating units according to the purpose. Preferably, X is —CH₂—, m is 1000 or more, n₁ is 0 or 1, and at least one of R₁, R₂, R₃, and R₄ preferably contains an ester group, an ether group, or a hydroxyl group. More preferably, m is 5000 or more, n₁ is 0, and at least one of R₁, R₂, R₃, and R₄ preferably contains an ester group or a hydroxyl group.

Examples of the alkyl group include a linear or branched saturated hydrocarbon having 1 to 10 carbon atoms, and a cyclic saturated hydrocarbon. Examples of the alkenyl group include vinyl, allyl, butynyl, and cyclohexenyl groups. Examples of the alkynyl group include ethynyl, 1-propynyl, 2-propynyl, 1-butynyl, 2-butynyl, hexynyl, octynyl, and heptynyl groups. Examples of the aryl group include phenyl, tolyl, naphthyl, and anthracenyl groups. Examples of the aralkyl group include benzyl and phenethyl groups. Examples of the epoxy group include a glycidyl ether group, and examples of the alkoxysilyl group include trimethoxysilyl, triethoxysilyl, and triethoxysilylethyl groups. Examples of the (meth)acrylic group include a methacryloxymethyl group, and examples of the ester group include methyl ester, ethyl ester, n-propyl ester, n-butyl ester, and t-butyl ester groups.

The one or more kinds of resin materials may be polyether ether ketone (PEEK), polyphenylene oxide (PPO), or other resins. For PEEK, EXPEEK manufactured by KURABO INDUSTRIES LTD. can be used, for example.

The resin multilayer substrate 10 may not have the bent portion 12a.

Note that a high-frequency transmission signal line has been described as an example of the resin multilayer substrate 10. However, the resin multilayer substrate 10 may be a high frequency circuit board such as an antenna.

The first interlayer connecting conductor v1, the second interlayer connecting conductor v2, and the interlayer connection conductors v11 and v12 may be through-hole conductors. The through-hole conductors are formed by plating the through-holes formed in the resin sheets 16a to 16d with Cu. In a case of using a plating method, it is common that the through-holes formed across a plurality of insulating layers are plated after stacking, but since the through-holes are metal-bonded with the same metal, the reliability of connection is high, and conductor resistance is easily reduced.

### DESCRIPTION OF REFERENCE SYMBOLS

1: Electronic device
10: Resin multilayer substrate
12: Laminate
12a: Bent portion
16, 16a to 16d: Resin sheet
17a, 17b: Resist layer
18: Signal conductor layer
20: First ground conductor layer
22: Second ground conductor layer

1. A resin sheet comprising:
one or more kinds of resin materials; and
a liquid crystal polymer,
wherein the one or more kinds of resin materials are a fluororesin,
a highest melting point among melting points of the one or more kinds of resin materials is lower than a melting point of the liquid crystal polymer by 30° C. or more,
a weight of the liquid crystal polymer is less than a total weight of the one or more kinds of resin materials, and
the resin sheet has a thermal expansion coefficient in a plane direction smaller than a thermal expansion coefficient in the plane direction of a comparative resin sheet containing the one or more kinds of resin materials and not containing the liquid crystal polymer.

2. The resin sheet according to claim 1, wherein the fluororesin is perfluoroalkoxyalkane.

3. The resin sheet according to claim 1, wherein the thermal expansion coefficient of the resin sheet in the plane direction is 5 ppm/° C. to 20 ppm/° C.

4. The resin sheet according to claim 1, wherein the thermal expansion coefficient of the resin sheet in the plane direction is 10 ppm/° C. to 20 ppm/° C.

5. The resin sheet according to claim 1, wherein the resin sheet contains 100 parts by weight of the one or more kinds of resin materials and 10 parts by weight to 70 parts by weight of the liquid crystal polymer.

6. The resin sheet according to claim 1, wherein the resin sheet contains 100 parts by weight of the one or more kinds of resin materials and 15 parts by weight to 50 parts by weight of the liquid crystal polymer.

7. The resin sheet according to claim 1, wherein the resin sheet contains 100 parts by weight of the one or more kinds of resin materials and 20 parts by weight to 40 parts by weight of the liquid crystal polymer.

8. The resin sheet according to claim 1, wherein the liquid crystal polymer is a thermotropic liquid crystal polymer.

9. A resin multilayer substrate comprising a laminate having a stacked plurality of the resin sheets according to claim 1.

10. The resin multilayer substrate according to claim 9, wherein the resin multilayer substrate includes a bent portion.

11. A resin sheet comprising:
one or more kinds of resin materials; and
a liquid crystal polymer,
wherein the one or more kinds of resin materials is a norbornene-based polymer containing at least one of repeating units represented by the following formula (1): 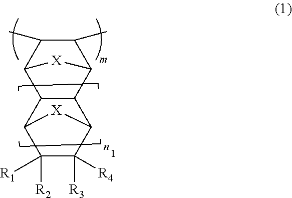
wherein
X represents O, —CH₂— or —CH₂—CH₂—;
each of substituents R₁, R₂, R₃, and R₄ represents a group containing a group selected from hydrogen, a linear or branched organic group, or a derivative in which a part of these linear or branched organic groups is substituted with a halogen or a nitrile group;
m is an integer of 10 to 10000; and
n₁ is an integer of 0 to 5,
a highest melting point among melting points of the one or more kinds of resin materials is lower than a melting point of the liquid crystal polymer by 30° C. or more,
a weight of the liquid crystal polymer is less than a total weight of the one or more kinds of resin materials, and
the resin sheet has a thermal expansion coefficient in a plane direction smaller than a thermal expansion coefficient in the plane direction of a comparative resin sheet containing the one or more kinds of resin materials and not containing the liquid crystal polymer.

12. The resin sheet according to claim 11, wherein the thermal expansion coefficient of the resin sheet in the plane direction is 5 ppm/° C. to 20 ppm/° C.

13. The resin sheet according to claim 11, wherein the thermal expansion coefficient of the resin sheet in the plane direction is 10 ppm/° C. to 20 ppm/° C.

14. The resin sheet according to claim 11, wherein the resin sheet contains 100 parts by weight of the one or more kinds of resin materials and 10 parts by weight to 70 parts by weight of the liquid crystal polymer.

15. The resin sheet according to claim 11, wherein the resin sheet contains 100 parts by weight of the one or more kinds of resin materials and 15 parts by weight to 50 parts by weight of the liquid crystal polymer.

16. The resin sheet according to claim 11, wherein the resin sheet contains 100 parts by weight of the one or more kinds of resin materials and 20 parts by weight to 40 parts by weight of the liquid crystal polymer.

17. The resin sheet according to claim 11, wherein the liquid crystal polymer is a thermotropic liquid crystal polymer.

18. A resin multilayer substrate comprising a laminate having a stacked plurality of the resin sheets according to claim 11.

19. The resin multilayer substrate according to claim 18, wherein the resin multilayer substrate includes a bent portion.
